(19) United States
(12) Patent Application Publication
(10) Pub. No.: US 2024/0322106 A1
(43) Pub. Date: Sep. 26, 2024

(54) Heat dissipation module

(71) Applicant: Coretronic Corporation, Hsin-Chu (TW)

(72) Inventor: SHAO-PENG SU, Hsin-Chu (TW)

(21) Appl. No.: 18/613,120

(22) Filed: Mar. 22, 2024

(30) Foreign Application Priority Data
Mar. 23, 2023 (CN) 202310289150.8

(51) Int. Cl. H01L 33/64; H01L 23/38

(52) U.S. Cl. CPC H01L 33/645; H01L 23/38; H01L 33/642

(57) ABSTRACT

A heat dissipation module includes an airtight structure and a thermoelectric cooling element. The airtight structure includes a first workpiece, a second workpiece and a compressible element. The first workpiece has a first airtight portion having a plurality of first protrusions. The second workpiece configured in alignment with the first workpiece has a second airtight portion having a plurality of second protrusions. The compressible element is configured between the first airtight portion and the second airtight portion, wherein a part of the compressible element is located in gaps of the first protrusions and gaps of the second protrusions. The thermoelectric cooling element configured between the first workpiece and the second workpiece partially contacts the first workpiece, wherein the heating element is configured on a side of the first workpiece away from the thermoelectric cooling element.

### CROSS-REFERENCE TO RELATED APPLICATION

This application claims the priority benefit of China Application No. 202310289150.8, filed on Mar. 23, 2023. The entirety of the above-mentioned patent application is hereby incorporated by reference herein and made a part of this specification.

### TECHNICAL FIELD

The disclosure relates to a heat dissipation module, and more particularly to a heat dissipation module with an airtight structure.

### BACKGROUND

If the heat energy generated by a heating element is not properly dissipated during operation, the heat energy may be accumulated in the heating element. When the temperature of the heating element is too high, it may cause malfunction of the heating element, and thus it is important to dissipate heat from the heating element. The conventional heat dissipation methods could be roughly divided into passive heat dissipation and active heat dissipation. Passive heat dissipation elements include a heat sink fin, and active heat dissipation elements include a heat-dissipating fan, a thermoelectric cooling element, and the like. Because the temperature of the cold surface of the thermoelectric cooling element is lower than the ambient temperature, an airtight design may be adopted to cover the cold surface to avoid the problem of moisture infiltration and condensation. However, the conventional airtight design has poor airtight effect due to the tolerance or assembly problems.

The information disclosed in this “BACKGROUND” section is only for enhancement understanding of the background of the disclosure and therefore it may contain information that does not form the prior art that is already known to a person of ordinary skill in the art. Furthermore, the information disclosed in this “BACKGROUND” section does not mean that one or more problems to be solved by one or more embodiments of the disclosure were acknowledged by a person of ordinary skill in the art.

### SUMMARY

The disclosure provides a heat dissipation module, which can improve airtight effect.

The disclosure provides another heat dissipation module, which can improve airtight effect.

Other advantages and objects of the disclosure may be further illustrated by the technical features broadly embodied and described as follows.

In order to achieve one or a portion of or all of the objects or other objects, an embodiment of the disclosure provides a heat dissipation module suitable for dissipating heat from a heating element. The heat dissipation module includes an airtight structure and a thermoelectric cooling element. The airtight structure includes a first workpiece, a second workpiece and a compressible element. The first workpiece has a first airtight portion having a plurality of first protrusions. The second workpiece configured in alignment with the first workpiece has a second airtight portion having a plurality of second protrusions. The compressible element is configured between the first airtight portion and the second airtight portion, wherein a part of the compressible element is located in gaps of the first protrusions and gaps of the second protrusions. The thermoelectric cooling element configured between the first workpiece and the second workpiece partially contacts the first workpiece, wherein the heating element is configured on a side of the first workpiece away from the thermoelectric cooling element.

In order to achieve one or a portion of or all of the objects or other objects, another embodiment of the disclosure provides a heat dissipation module suitable for dissipating heat from a heating element. The heat dissipation module includes an airtight structure and a thermoelectric cooling element. The airtight structure includes a first workpiece, a second workpiece and a compressible element. The second workpiece is configured in alignment with the first workpiece. The compressible element is configured between the first workpiece and the second workpiece, and has a body and a plurality of protrusions extending from the body toward the first workpiece and the second workpiece. The adjacent two protrusions located on a same side have a gap. The thermoelectric cooling element is configured between the first workpiece and the second workpiece and partially contacts the first workpiece. The heating element is configured on a side of the first workpiece away from the thermoelectric cooling element.

Because the first airtight portion of the first workpiece has a plurality of first protrusions and the second airtight portion of the second workpiece has a plurality of second protrusions, the heat dissipation module in one embodiment of the disclosure can improve the airtight effect, thereby avoiding the problem of moisture infiltration and condensation. In addition, because the compressible element has a plurality of protrusions extending in a direction towards the first workpiece and the second workpiece, the heat dissipation module in another embodiment of the disclosure can improve the airtight effect, thereby avoiding the problem of moisture infiltration and condensation.

Other objectives, features and advantages of the disclosure will be further understood from the further technological features disclosed by the embodiments of the disclosure wherein there are shown and described preferred embodiments of this disclosure, simply by way of illustration of modes best suited to carry out the disclosure.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view of a heat dissipation module according to an embodiment of the disclosure;

FIG. 2 is a schematic cross-sectional view of a heat dissipation module according to another embodiment of the disclosure;

FIG. 3 is a schematic cross-sectional view of a heat dissipation module according to another embodiment of the disclosure; and

FIG. 4 is a schematic cross-sectional view of a heat dissipation module according to another embodiment of the disclosure.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. The components of the disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the disclosure. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing”, “faces”, and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

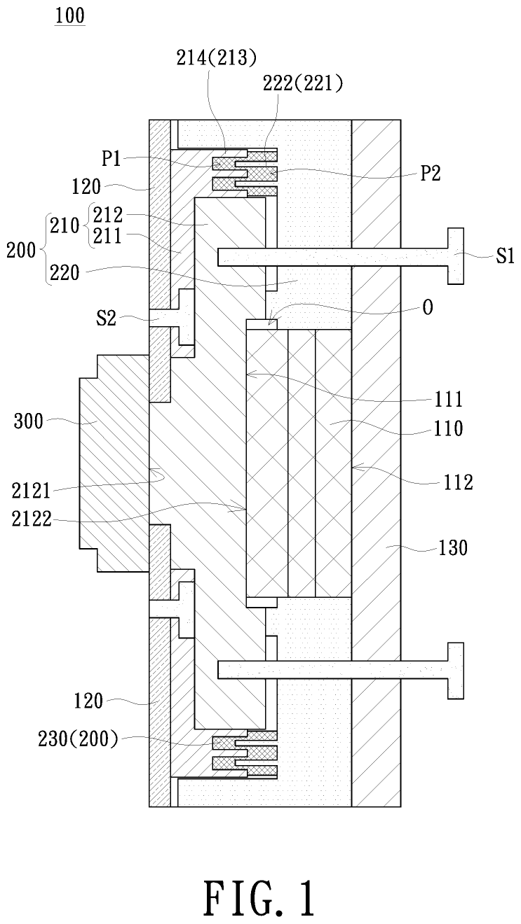

FIG. 1 is a schematic cross-sectional view of a heat dissipation module according to an embodiment of the disclosure. Referring to FIG. 1, the heat dissipation module 100 of this embodiment is suitable for dissipating heat from a heating element 300. The heat dissipation module 100 includes an airtight structure 200 and a thermoelectric cooling element 110. The airtight structure 200 includes a first workpiece 210, a second workpiece 220 and a compressible element 230. The first workpiece 210 has a first airtight portion 213 and the first airtight portion 213 has a plurality of first protrusions 214. The second workpiece 220 is configured in alignment with the first workpiece 210 and has a second airtight portion 221. The second airtight portion 221 has a plurality of second protrusions 222. The compressible element 230 is configured between the first airtight portion 213 and the second airtight portion 221, and a part of the compressible element 230 is located in gaps P1 of the first protrusions 214 and gaps P2 of the second protrusions 222. That is to say, the first protrusions 214 may compress the compressible element 230 in the gaps P2 between the second protrusions 222, and the second protrusions 222 may compress the compressible element 230 in the gaps P1 between the first protrusions 214. Specifically, the compressible element 230 is, for example, sponge or rubber, but the disclosure is not limit thereto. The thermoelectric cooling element 110 is configured between the first workpiece 210 and the second workpiece 220 and partially contacts the first workpiece 210. The heating element 300 is configured on a side of the first workpiece 210 away from the thermoelectric cooling element 110. Specifically, the thermoelectric cooling element 110 could be an active heat dissipation element, such as a thermoelectric cooling (TEC) device.

Specifically, the two opposite sides of the first workpiece 210 of this embodiment are connected to the heating element 300 and the thermoelectric cooling element 110 respectively, so the heat energy generated by the heating element 300 could be conducted to the thermoelectric cooling element 110 by the first workpiece 210, which helps the heat dissipation of the heating element 300. The thermoelectric cooling element 110 is configured between the first workpiece 210 and the second workpiece 220. In addition, to avoid the risk of condensation caused by the hot air with moisture contacting the cold surface 111 of the thermoelectric cooling element 110, the airtight structure 200 of this embodiment is provided with the first airtight portion 213 and the second airtight portion 221 configured around the first workpiece 210 and the second workpiece 220 respectively. In this embodiment, the first protrusions 214 of the first airtight portion 213 are annular protrusions formed around the first workpiece 210. The second protrusions 222 of the second airtight portion 221 are annular protrusions formed around the second workpiece 220. The distances from each of the first protrusions 214 of the first airtight portion 213 to a center of the first workpiece 210 are, for example, different. The distances from each of the second protrusions 222 of the second airtight portion 221 to a center of the second workpiece 220 are, for example, different. That is, the plurality of first protrusions 214 can also be configured around the center of the first workpiece 210, and the plurality of second protrusions 222 can also be configured around the center of the second workpiece 220, but the disclosure is not limited thereto.

For example, the contours of the first workpiece 210 and the second workpiece 220 are square (viewed in the direction from the heating element 300 to the thermoelectric cooling element 110). The first airtight portion 213 and the second airtight portion 221 are, for example, respectively configured on a periphery of the first workpiece 210 and a periphery of the second workpiece 220, so the thermoelectric cooling element 110 can be surrounded by the first airtight portion 213 and the second airtight portion 221. In this embodiment, the quantity of the plurality of first protrusions 214 is, for example, three, and the quantity of the plurality of second protrusions 222 is, for example, two, so that the first protrusions 214 and the second protrusions 222 can be closely configured with each other. In addition, in this embodiment, the use of the compressible element 230 in cooperation with the first airtight portion 213 and the second airtight portion 221 can improve the airtight effect. Specifically, the compressible element 230 is compressed through the first protrusions 214 and the second protrusions 222 when the compressible element 230 is configured between the first airtight portion 213 and the second airtight portion 221, so that the compressible element 230 can fill the gaps P1 between the first protrusions 214 and the gap P2 between the second protrusions 222.

In other words, when the first workpiece 210 is assembled with the second workpiece 220, the first airtight portion 213 and the second airtight portion 221 make the compressible element 230 fill the gaps P1 and P2 between the first airtight portion 213 and the second airtight portion 213 by the first protrusions 214 and the second protrusions 222, so as to prevent hot air with moisture from infiltrating and condensing on the cold surface 111 of the thermoelectric cooling element 110. The disclosure does not specifically limit the contours of the first workpiece 210 and the second workpiece 220, the configuration positions, shapes and quantities of the first protrusions 214 and the second protrusions 222.

The first workpiece 210 in this embodiment includes, for example, a carrier frame 211 and a metal heat conduction plate 212. The carrier frame 211 has, for example, the first airtight portion 213. The metal heat conduction plate 212 is, for example, configured between the carrier frame 211 and the second workpiece 220. A first side 2121 of the metal heat conduction plate 212, for example, partially contacts the heating element 300, and a second side 2122 of the metal heat conduction plate 2120, for example, partially contacts the thermoelectric cooling element 110. In addition, the second workpiece 220 has, for example, an opening O for accommodating the thermoelectric cooling element 110, so that the thermoelectric cooling element 110 is fixed on the second workpiece 220. Specifically, the metal heat conduction plate 212 is, for example, a metal with good thermal conductivity, such as copper. The thermoelectric cooling element 110 has, for example, a cold surface 111 and a hot surface 112 opposite to the cold surface 111. The cold surface 111, for example, partially contacts the metal heat conduction plate 212, and the hot surface 112, for example, partially contacts the second workpiece 220. The metal heat conduction plate 212 is, for example, in contact with the heating element 300 and the cold surface 111 of the thermoelectric cooling element 110 respectively and the metal heat conduction plate 212 is good for conducting heat energy, thus, the heat dissipation effect of the heating element 300 can be improved. In addition, in the heat dissipation module 100 of this embodiment, the first protrusions 214 and the second protrusions 222 are located, for example, on a periphery of the metal heat conduction plate 212, that is, the metal heat conduction plate 212 is surrounded by the first airtight portion 213 and the second airtight portion 221.

Please continue to refer to FIG. 1. The heat dissipation module 100 of this embodiment, for example, further includes a heat dissipation element base 130 configured on the side of the second workpiece 220 away from the first workpiece 210. Specifically, the heat dissipation element base 130 is, for example, in contact with the hot surface 112 of the thermoelectric cooling element 110. The heat dissipation element base 130 is, for example, a heat dissipation fin that can conduct heat energy, so that the heat energy of the thermoelectric cooling element 110 can be conducted out through the heat dissipation element base 130 to avoid accumulating heat energy. In addition, the heat dissipation module 100 may further include a substrate 120. The carrier frame 211, for example, carries the substrate 120, and the heating element 300 is, for example, electrically connected to the substrate 120. For example, the substrate 120 is a printed circuit board. The carrier frame 211 is, for example, made of insulating material, but the disclosure does not specifically limit the material of the carrier frame 211. The heating element 300 in this embodiment is, for example, a light valve, such as a digital micromirror device (DMD), or a liquid crystal on silicon (LCoS) panel, but the disclosure is not limited thereto.

The heat dissipation module 100 of this embodiment may include a plurality of fasteners S1 and S2. The fasteners S1 penetrate the heat dissipation element base 130 and the second workpiece 220 and then extend into the metal heat conduction plate 212. The thermoelectric cooling element 110 is configured on the second workpiece 220, for example, so the thermoelectric cooling element 110 can be closely connected with the metal heat conduction plate 212 through the fasteners S1, thereby compressing the compressible element 230 to form a good airtight effect. In addition, the fasteners S2 are, for example, used to penetrate the carrier frame 211 and the substrate 120, so that the carrier frame 211 and the substrate 120 are fixed to each other. The heating element 300 is connected to the substrate 120, so the heating element 300 and the carrier frame 211 can be fixed to each other by the fasteners S2. In this way, the fasteners S1 and S2 can make the heating element 300 and the thermoelectric cooling element 110 closely connected with each other through the metal heat conduction plate 212, thereby increasing the heat dissipation effect of the heating element 300. The fasteners S1 and S2 in this embodiment are, for example, screws, but the disclosure is not limited thereto. In another embodiment, the heat dissipation module 100 may not include the fasteners S1, S2, and other methods may be used to fasten the airtight structure 200.

In the heat dissipation module 100 of this embodiment, the first airtight portion 213 of the first workpiece 210 has a plurality of first protrusions 214 and the second airtight portion 221 of the second workpiece 220 has a plurality of second protrusions 222, so the airtight effect can be improved to avoid the problem of hot and humid air infiltration and condensation.

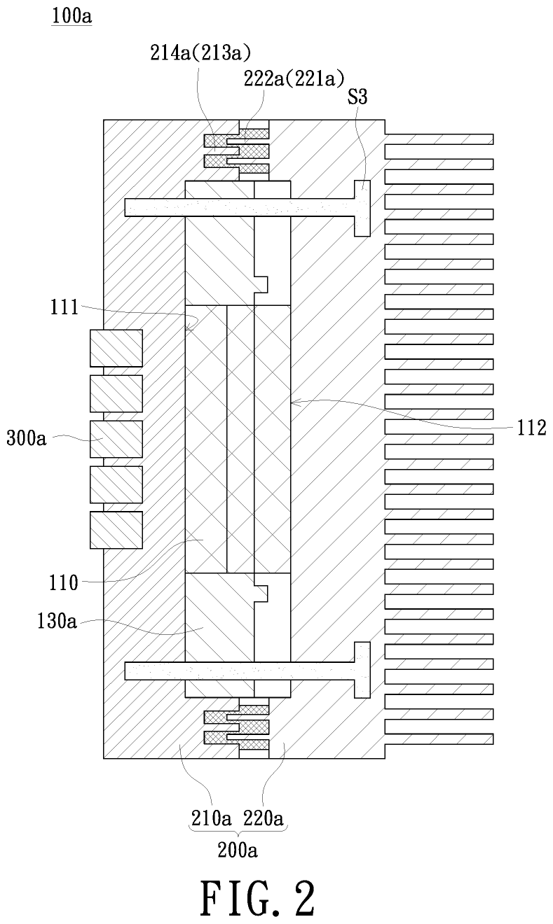

FIG. 2 is a schematic cross-sectional view of a heat dissipation module according to another embodiment of the disclosure. Please refer to FIG. 2. The heat dissipation module 100a of this embodiment is similar to the heat dissipation module 100, and the main differences are that the first workpiece 210a of the heat dissipation module 100a is, for example, a carrier frame for carrying the heating element 300a and does not include a metal heat conduction plate 212, the heat dissipation element base 130a is, for example, configured between the first workpiece 210a and the second workpiece 220a and carries the thermoelectric cooling element 110, and the hot surface 112 of the thermoelectric cooling element 110, for example, partially contacts the second workpiece 220a. Specifically, the heating element 300a is, for example, directly configured on the first workpiece 210a, and the first workpiece 210a, for example, partially contacts the cold surface 111 of the thermoelectric cooling element 110, so that the heat energy generated by the heating element 300a is, for example, conducted to the thermoelectric cooling element 110 through the first workpiece 210a, and the heat energy of the thermoelectric cooling element 110 can be conducted to the second workpiece 220a, thereby avoiding accumulating heat energy. In addition, the first protrusions 214a of the first airtight portion 213a and the second protrusions 222a of the second airtight portion 221a in this embodiment are, for example, located on a periphery of the heat dissipation element base 130a.

The heating element 300a in this embodiment is, for example, a light emitting element and may include a plurality of point light sources. The point light sources are, for example, light emitting diodes, but the disclosure is not limited thereto. On the other hand, the heat dissipation module 100a of this embodiment may include a plurality of fasteners S3, so that the airtight effect of the airtight structure 200a is better. For example, the fasteners S3 penetrate the second workpiece 220a and the heat dissipation element base 130a and then extend into the first workpiece 210a. The thermoelectric cooling element 110 is, for example, configured on the heat dissipation element base 130a, so that the thermoelectric cooling element 110 can be closely connected with the first workpiece 210a through the fasteners S3, thereby increasing the heat dissipation effect of the heating element 300a. The fasteners S3 in this embodiment are, for example, screws, but the disclosure is not limited thereto.

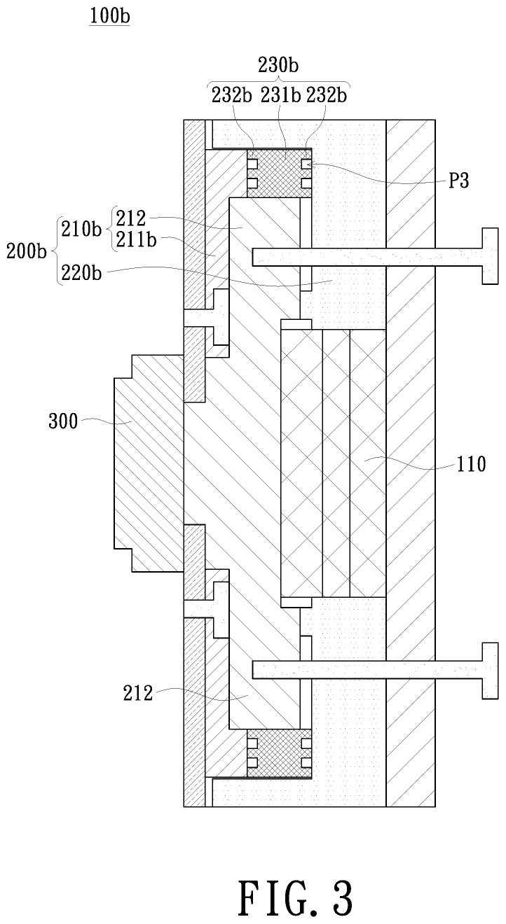

FIG. 3 is a schematic cross-sectional view of a heat dissipation module according to another embodiment of the disclosure. Please refer to FIG. 1 and FIG. 3 together. The heat dissipation module 100b of this embodiment is similar to the heat dissipation module 100. The main differences are that the compressible element 230b of this embodiment has a plurality of protrusions 232b, while the first workpiece 210b and the second workpiece 220b do not have the plurality of first protrusions 214 and the plurality of second protrusions 222. Specifically, the heat dissipation module 100b of this embodiment includes an airtight structure 200b and a thermoelectric cooling element 110. The airtight structure 200b includes a first workpiece 210b, a second workpiece 220b, and a compressible element 230b. The second workpiece 220b is configured to be aligned with the first workpiece 210b, and the compressible element 230b is configured between the first workpiece 210b and the second workpiece 220b. The compressible element 230b has a body 231b and a plurality of protrusions 232b extending in a direction from the body 231b to the first workpiece 210b and the second workpiece 220b. There are gaps P3 between the adjacent two protrusions 232b located on the same side. The adjacent two protrusions located on a same side have a gap P3. The thermoelectric cooling element 110 is configured between the first workpiece 210b and the second workpiece 220b and partially contacts the first workpiece 210b. The heating element 300 is configured on the side of the first workpiece 210b away from the thermoelectric cooling element 110. The first workpiece 210b and the second workpiece 220b, for example, compress the compressible element 230b, and the protrusions 232b of the compressible element 230b fill the gaps P3. That is, the protrusions 232b of the compressible element 230b are, for example, deformed to fill the gaps P3.

Specifically, the compressible element 230b of the heat dissipation module 100b in this embodiment has a plurality of protrusions 232b. In addition, there are gaps P3 between the protrusions 232b. Thus, when the first workpiece 210b and the second workpiece 220b are configured to be aligned with each other and squeeze the compressible element 230b, the protrusions 232b can be deformed to fill the gaps P3, thereby achieving an airtight effect between the first workpiece 210b and the second workpiece 220b. In other words, if there is a tolerance between the first workpiece 210b and the second workpiece 220b so that the first workpiece 210b and the second workpiece 220b may compress the protrusions 232b of the compressible element 230b when the first workpiece 210b and the second workpiece 220b are configured to be aligned with each other, the protrusions 232b that are deformed due to the tolerance can fill the gaps P3. In this embodiment, the quantity of the plurality of protrusions 232b extending in a direction toward the first workpiece 210b and the second workpiece 220b is, for example, three, but the disclosure is not limited thereto. It should be noted that the quantity of the gaps P3 between the protrusions 232b is, for example, more than two, which has a better airtight effect.

In addition, the protrusions 232b of the compressible element 230b are, for example, located on a periphery of the metal heat conduction plate 212. On the other hand, compared with the embodiment shown in FIG. 1 in which the first workpiece 210 and the second workpiece 220 are respectively provided with the first protrusions 214 and the second protrusions 222, the cost of this embodiment in which the protrusions 232b are disposed on the compressible element 230b is relatively low, which has a cost advantage in manufacturing.

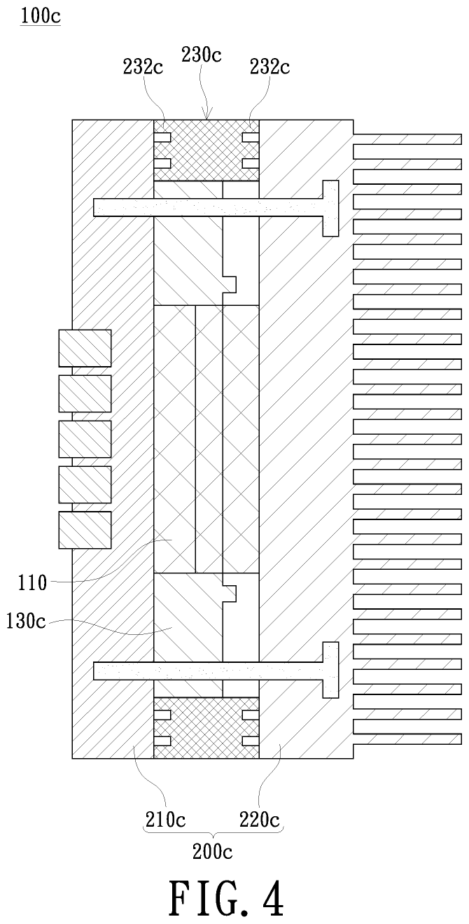

Because the compressible element 230b has a plurality of protrusions 232b extending in a direction towards the first workpiece 210b and the second workpiece 220b, the heat dissipation module 100b of this embodiment can improve the airtight effect, thereby avoiding the problem of moisture infiltration and condensation. In addition, the compressible element 230b of this embodiment can be applied to the heat dissipation module 100a shown in FIG. 2, and please see FIG. 4 for the details.

FIG. 4 is a schematic cross-sectional view of a heat dissipation module according to another embodiment of the disclosure. Please refer to FIGS. 2 and 4. The heat dissipation module 100c of this embodiment is similar to the heat dissipation module 100a. The main differences are that the compressible element 230c of this embodiment has a plurality of protrusions 232c, while the first workpiece 210c and the second workpiece 220c do not have the first protrusions 214a and the second protrusions 222a shown in FIG. 2. In addition, the protrusions 232c of the compressible element 230c of the heat dissipation module 100c of this embodiment are located, for example, on a periphery of the heat dissipation element base 130c.

To sum up, because the first airtight portion of the first workpiece has a plurality of first protrusions and the second airtight portion of the second workpiece has a plurality of second protrusions, the heat dissipation module in one embodiment of the disclosure can improve the airtight effect, thereby avoiding the problem of moisture infiltration and condensation. In addition, because the compressible element has a plurality of protrusions extending in a direction towards the first workpiece and the second workpiece, the heat dissipation module in another embodiment of the disclosure can improve the airtight effect, thereby avoiding the problem of moisture infiltration and condensation.

The foregoing description of the preferred embodiment of the disclosure has been presented for purposes of illustration and description. It is not intended to be exhaustive or to limit the disclosure to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the disclosure and its best mode practical application, thereby to enable persons skilled in the art to understand the disclosure for various embodiments and with various modifications as are suited to the particular use or implementation contemplated. It is intended that the scope of the disclosure be defined by the claims appended hereto and their equivalents in which all terms are meant in their broadest reasonable sense unless otherwise indicated. Therefore, the term “the disclosure” is not necessary limited the claim scope to a specific embodiment, and the reference to particularly preferred exemplary embodiments of the disclosure does not imply a limitation on the disclosure, and no such limitation is to be inferred. The disclosure is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the disclosure. It should be appreciated that variations may be made in the embodiments described by persons skilled in the art without departing from the scope of the disclosure as defined by the following claims. Moreover, no element and component in the disclosure is intended to be dedicated to the public regardless of whether the element or component is explicitly recited in the following claims. Furthermore, the terms such as the first workpiece, the second workpiece, the first airtight portion, the second airtight portion, the first protrusion, and the second protrusion are only used for distinguishing various elements and do not limit the number of the elements.

What is claimed is:

1. A heat dissipation module, suitable for dissipating heat from a heating element, the heat dissipation module comprising:
an airtight structure, comprising:
a first workpiece, having a first airtight portion, wherein the first airtight portion has a plurality of first protrusions;
a second workpiece, configured in alignment with the first workpiece and having a second airtight portion, wherein the second airtight portion has a plurality of second protrusions; and
a compressible element, configured between the first airtight portion and the second airtight portion, wherein a part of the compressible element is located in gaps of the first protrusions and gaps of the second protrusions; and
a thermoelectric cooling element, configured between the first workpiece and the second workpiece and partially contacting the first workpiece, wherein the heating element is configured on a side of the first workpiece away from the thermoelectric cooling element.

2. The heat dissipation module according to claim 1, wherein distances from each of the first protrusions to a center of the first workpiece are different, and distances from each of the second protrusions to a center of the second workpiece are different.

3. The heat dissipation module according to claim 1, wherein the first workpiece comprises:
a carrier frame, having the first airtight portion; and
a metal heat conduction plate, configured between the carrier frame and the second workpiece, wherein a first side surface of the metal heat conduction plate partially contacts the heating element, and a second side surface of the metal heat conduction plate partially contacts the thermoelectric cooling element.

4. The heat dissipation module according to claim 3, further comprising a substrate, wherein the carrier frame carries the substrate, and the heating element is electrically connected to the substrate.

5. The heat dissipation module according to claim 3, wherein the thermoelectric cooling element has a cold surface and a hot surface opposite to the cold surface, the cold surface partially contacts the metal heat conduction plate, the hot surface partially contacts the second workpiece, and the second workpiece has an opening for accommodating the thermoelectric cooling element.

6. The heat dissipation module according to claim 3, wherein the first protrusions and the second protrusions are located around a periphery of the metal heat conduction plate.

7. The heat dissipation module according to claim 1, further comprising a heat dissipation element base, configured on a side of the second workpiece away from the first workpiece.

8. The heat dissipation module according to claim 1, further comprising a heat dissipation element base, configured between the first workpiece and the second workpiece and carrying the thermoelectric cooling element, wherein the thermoelectric cooling element has a cold surface and a hot surface opposite to the cold surface, the cold surface partially contacts the first workpiece, and the hot surface partially contacts the second workpiece.

9. The heat dissipation module according to claim 8, wherein the first protrusions and the second protrusions are located on a periphery of the heat dissipation element base.

10. The heat dissipation module according to claim 1, wherein the heating element comprises a light valve or a light emitting element.

11. A heat dissipation module, suitable for dissipating heat from a heating element, the heat dissipation module comprising:
an airtight structure, comprising:
a first workpiece;
a second workpiece, configured in alignment with the first workpiece; and
a compressible element, configured between the first workpiece and the second workpiece, wherein the compressible element has a body and a plurality of protrusions extending from the body toward the first workpiece and the second workpiece, and wherein the adjacent two protrusions located on a same side have a gap;
a thermoelectric cooling element, configured between the first workpiece and the second workpiece and partially contacting the first workpiece, wherein the heating element is configured on a side of the first workpiece away from the thermoelectric cooling element.

12. The heat dissipation module according to claim 11, wherein the protrusions of the compressible element fill the gaps.

13. The heat dissipation module according to claim 11, wherein the first workpiece comprises:
a carrier frame, having a first airtight portion; and
a metal heat conduction plate, configured between the carrier frame and the second workpiece, wherein a first side of the metal heat conduction plate partially contacts the heating element, and a second side of the metal heat conduction plate partially contacts the thermoelectric cooling element.

14. The heat dissipation module according to claim 13, further comprising a substrate, wherein the carrier frame carries the substrate, and the heating element is electrically connected to the substrate.

15. The heat dissipation module according to claim 13, wherein the thermoelectric cooling element has a cold surface and a hot surface opposite to the cold surface, the cold surface partially contacts the metal heat conduction plate, the hot surface partially contacts the second workpiece, and the second workpiece has an opening for accommodating the thermoelectric cooling element.

16. The heat dissipation module according to claim 13, wherein the protrusions of the compressible element are located around a periphery of the metal heat conduction plate.

17. The heat dissipation module according to claim 11, further comprising a heat dissipation element base, configured on a side of the second workpiece away from the first workpiece.

18. The heat dissipation module according to claim 11, further comprising a heat dissipation element base, configured between the first workpiece and the second workpiece and carrying the thermoelectric cooling element, wherein the thermoelectric cooling element has a cold surface and a hot surface opposite to the cold surface, the cold surface partially contacts the first workpiece, and the hot surface partially contacts the second workpiece.

19. The heat dissipation module according to claim 18, wherein the protrusions of the compressible element are located on a periphery of the heat dissipation element base.

20. The heat dissipation module according to claim 11, wherein the heating element comprises a light valve or a light emitting element.
